(19) United States
(12) Patent Application Publication
(10) Pub. No.: US 2025/0224452 A1
(43) Pub. Date: Jul. 10, 2025

(54) CURRENT COLLECTOR DIAGNOSIS

(71) Applicant: GM GLOBAL TECHNOLOGY OPERATIONS LLC, DETROIT, MI (US)

(72) Inventors: Kevin Leslie Campbell, Farmington Hills, MI (US); Benjamin Christian, Plymouth, MI (US)

(21) Appl. No.: 18/407,561

(22) Filed: Jan. 9, 2024

(51) Int. Cl. G01R 31/3835; G01N 3/317; G01R 19/00; G01R 31/392; H01M 10/42

(52) U.S. Cl. CPC G01R 31/3835; G01N 3/317; G01R 19/0007; G01R 31/392; H01M 10/4285; G01N 2203/0067

(57) ABSTRACT

Techniques are provided for current collector diagnosis. In one embodiment, the techniques involve determining that a current is flowing through a current collector of the battery cell, generating a mechanical excitation to the current collector, determining an amplitude of the voltage across the battery cell based on the mechanical excitation, and determining a presence of a tear or a separation of a foil of the current collector based on the amplitude of the voltage across the battery cell.

### INTRODUCTION

The subject disclosure relates to battery cell diagnosis, and more specifically, to diagnosing damage or tears of current collector foils of battery cells.

A lithium-ion cell generally includes current collector foils that facilitate electron flow between a cathode and an anode of a cell. However, the current collector foils may be damaged or develop tears, which can impede performance of the cell. Techniques for diagnosing current collector foils generally involve opening the cells and examining the current collector foils, which render the cells inoperable for later operations or applications.

### SUMMARY

In one exemplary embodiment, a method is provided to diagnose a battery cell of a vehicle. The method includes determining that a current is flowing through a current collector of the battery cell, generating a mechanical excitation to the current collector, determining an amplitude of a voltage across the battery cell based on the mechanical excitation, and determining a presence of a tear or a separation of a foil of the current collector based on the amplitude of the voltage across the battery cell.

In addition to one or more of the features described herein, the method also includes determining a time at which the tear or the separation of the foil of the current collector occurred.

In addition to one or more of the features described herein, the mechanical excitation is generated via a mechanical excitation unit disposed on or positioned at an external surface of the battery cell or a foil consolidation unit coupled to the battery cell.

In addition to one or more of the features described herein, the external surface includes one of: an anode tab of the battery cell, a cathode tab of the battery cell, or a surface in contact with a combination of an anode of the battery cell, a current collector at the anode, a foil extension region of the current collector at the anode, a cathode of the battery cell, a current collector at the cathode, a foil extension region of the current collector at the cathode, or a separator of the battery cell.

In addition to one or more of the features described herein, the mechanical excitation causes a displacement of the foil of the current collector, and wherein the displacement of the foil causes the tear or the separation to close and to open.

In addition to one or more of the features described herein, the voltage across the battery cell is passed through a high-pass filter or a band-pass filter before being measured by a voltage measurement unit.

In addition to one or more of the features described herein, the amplitude is determined within a frequency band with a lower cut off greater or equal to 1 Hertz.

In another exemplary embodiment, a system is provided to diagnose a battery cell of a vehicle. The system includes a processor, and memory or storage comprising an algorithm or computer instructions, which when executed by the processor, performs an operation that includes determining that a current is flowing through a current collector of the battery cell, generating a mechanical excitation to the current collector, determining an amplitude of a voltage across the battery cell based on the mechanical excitation, and determining a presence of a tear or a separation of a foil of the current collector based on the amplitude of the voltage across the battery cell.

In addition to one or more of the features described herein, the operation also includes determining a time at which the tear or the separation of the foil of the current collector occurred.

In addition to one or more of the features described herein, the mechanical excitation is generated via a mechanical excitation unit disposed on or positioned at an external surface of the battery cell or a foil consolidation unit coupled to the battery cell.

In addition to one or more of the features described herein, the external surface includes one of: an anode tab of the battery cell, a cathode tab of the battery cell, or a surface in contact with a combination of an anode of the battery cell, a current collector at the anode, a foil extension region of the current collector at the anode, a cathode of the battery cell, a current collector at the cathode, a foil extension region of the current collector at the cathode, or a separator of the battery cell.

In addition to one or more of the features described herein, the mechanical excitation causes a displacement of the foil of the current collector, and wherein the displacement of the foil causes the tear or the separation to close and to open.

In addition to one or more of the features described herein, the amplitude is determined within a frequency band with a lower cut off greater or equal to 1 Hertz.

In addition to one or more of the features described herein, the voltage across the battery cell is passed through a high-pass filter or a band-pass filter before being measured by a voltage measurement unit.

In yet another exemplary embodiment, a computer-readable storage medium having a computer-readable program code embodied therewith is provided to diagnose a battery cell of a vehicle. The computer-readable program code is executable by one or more computer processors to perform an operation that includes determining that a current is flowing through a current collector of the battery cell, generating a mechanical excitation to the current collector, determining an amplitude of a voltage across the battery cell based on the mechanical excitation, and determining a presence of a tear or a separation of a foil of the current collector based on the amplitude of the voltage across the battery cell.

In addition to one or more of the features described herein, the operation also includes determining a time at which the tear or the separation of the foil of the current collector occurred.

In addition to one or more of the features described herein, the mechanical excitation is generated via a mechanical excitation unit disposed on or positioned at an external surface of the battery cell or a foil consolidation unit coupled to the battery cell, and wherein the external surface includes one of: an anode tab of the battery cell, a cathode tab of the battery cell, or a surface in contact with a combination of an anode of the battery cell, a current collector at the anode, a foil extension region of the current collector at the anode, a cathode of the battery cell, a current collector at the cathode, a foil extension region of the current collector at the cathode, or a separator of the battery cell.

In addition to one or more of the features described herein, the mechanical excitation causes a displacement of the foil of the current collector, and wherein the displacement of the foil causes the tear or the separation to close and to open.

In addition to one or more of the features described herein, the amplitude is determined within a frequency band with a lower cut-off greater or equal to 1 Hertz.

In addition to one or more of the features described herein, the voltage across the battery cell is passed through a high-pass filter or a band-pass filter before being measured by a voltage measurement unit.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 illustrates a vehicle, according to an embodiment;

FIG. 2 illustrates a cell diagnosis environment, according to an embodiment;

FIG. 3 illustrates a computing environment, according to an embodiment; and

FIG. 4 illustrates a flowchart of a method of diagnosing a cell, according to an embodiment.

### DETAILED DESCRIPTION

The following description is merely exemplary in nature and is not intended to limit the present disclosure, its application or uses. It should be understood that throughout the drawings, corresponding reference numerals indicate like or corresponding parts and features. As used herein, the term “unit” refers to circuitry that may include an application specific integrated circuit (ASIC), an electronic circuit, a processor (shared, dedicated, or group) and memory that executes one or more software or firmware programs, a combinational logic circuit, and/or other suitable components that provide the described functionality. Further, the term “module” can refer to one or more algorithms, instruction sets, software applications, or other computer-readable program code that can be executed by a processor to perform the functions, operations, or processes described herein.

Embodiments of the present disclosure improve upon battery cell diagnosis techniques by providing a control that tests a cell via mechanical excitation to identify tears of a current collector of the cell. In one embodiment, a diagnostic module can control a vibration of a mechanical excitation unit, which can cause a current collector of a cell to vibrate. Afterwards, the controller can measure a voltage output of the cell, determine an amplitude of the voltage output, and determine damage (e.g., the presence of a tear or separation) of the current collector foil based on the determined amplitude.

One benefit of the disclosed embodiments is to diagnose damage of a current collector foil of a cell without harming the cell. Further, embodiments of the present disclosure can reduce the equipment required to diagnose damage of the current collector foil. Further, embodiments of the present disclosure can improve the accuracy of diagnosing the damage by obviating the need to consider high internal resistance or aging of the cell, thereby reducing false positives.

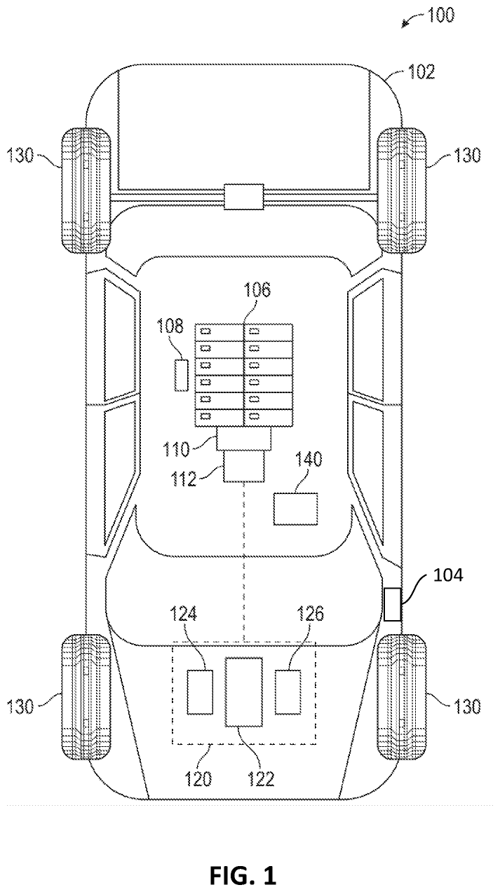

FIG. 1 illustrates a vehicle 100, according to an embodiment. The vehicle 100 includes a body 102, which can support a charge port 104, a power system 106, a sensor system 108, a propulsion system 120, a controller 140, and other systems of the vehicle 100 described herein.

In one embodiment, the vehicle 100 is an internal combustion engine (ICE) vehicle, an electric vehicle (EV), or a hybrid electric vehicle (HEV). In the illustrated embodiment, the vehicle 100 is an HEV that is partially powered by the power system 106, which includes multiple interconnected battery cells. The power system 106 can be charged via the charge port 104 that is connected to a power source (e.g., a grid, a charging station, another vehicle, or the like).

The power system 106 can be electrically coupled to at least one electric motor assembly of the propulsion system 120. In one embodiment, the power system 106 is electrically coupled to a direct current (DC) converter unit 110 (e.g., a DC-DC converter) and an inverter unit 112 (e.g., a traction power inversion unit). The inverter unit 112 can include multiple inverters that convert DC signals from the power system 106 to three-phase alternating current (AC) signals to drive electric motors of the propulsion system 120. The power system 106 can also be electrically coupled to vehicle electronics systems such as audio systems, display systems, navigation systems, temperature control systems, or the like.

The sensor system 108 includes a variety of sensors disposed on, or integrated with, various components of the vehicle 100. In one embodiment, the sensor system 108 is communicatively coupled to the controller 140 to transfer measurements of the power system 106 to the controller 140. The sensor system 108 may include a current sensor, a voltage sensor, a temperature sensor, or the like.

The propulsion system 120 can include an ICE system 122 and at least one electric motor assembly (e.g., a first electric motor 124 and a second electric motor 126). Each component of the propulsion system 120 can be configured to drive at least one the wheels 130 of the vehicle 100 via a transmission system coupled to a front axle shaft or a rear axle shaft, which are coupled to a respective front and rear set of the wheels 130.

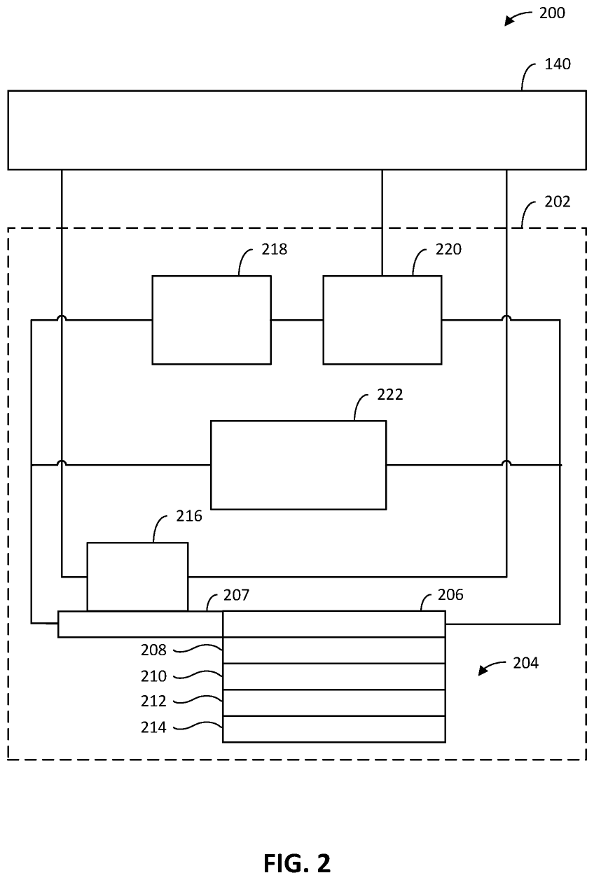

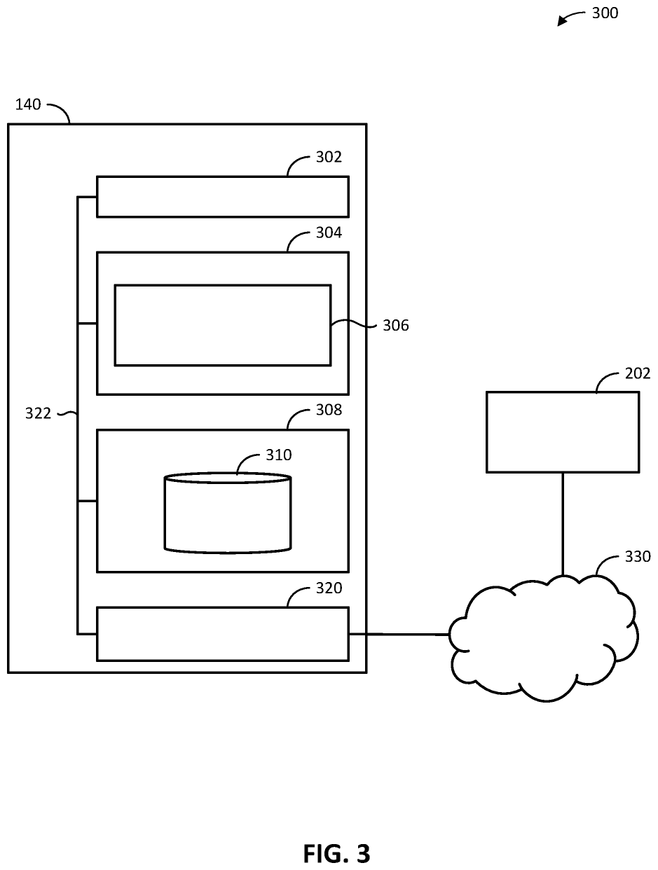

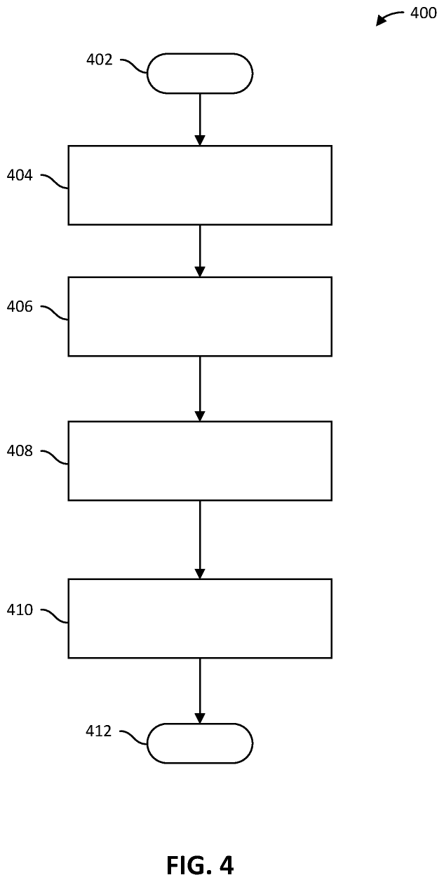

In one embodiment, the controller 140 is configured to diagnose a battery cell of the power system 106, and control the propulsion system 120, or other systems of the vehicle 100, based on the diagnosis. The controller is discussed in greater detail in FIGS. 2 and 3. Techniques used to diagnose the power system 106 are discussed in FIG. 4.

FIG. 2 illustrates a cell diagnosis environment 200, according to an embodiment. In the illustrated embodiment, the cell diagnosis environment 200 includes a testing unit 202 (which includes a cell 204, a mechanical excitation unit 216, an electrical load 222, a high-pass filter 218, a voltage measurement unit 220), and the controller 140. Embodiments of the present disclosure may reference a “lithium-ion” cell. However, any battery cell that includes a current collector may be used in accordance with aspects of the embodiments described herein.

In one embodiment, the cell 204 is a lithium-ion cell of the power system 106. The cell 204 can include a first current collector (e.g., current collector 206), an anode 208, a separator 210, a cathode 212, and a second current collector (e.g., current collector 214).

The first current collector can be positioned at the anode 208, and the second current collector can be positioned at the cathode 212. The anode 208 can be a lower potential terminal of the cell 204 that includes carbon graphite layers that store lithium atoms, and the cathode 212 can be a higher potential terminal of the cell 204 that includes a lithium metal oxide.

The current collectors can include metal foils or grids that bridge electrons from electro-chemical reactions within the cell 204 and the testing unit 202. In one embodiment, the first current collector includes a foil extension region 207. The foil extension region 207 can represent a portion of the first current collector that extends beyond an electrode body (e.g., the anode 208 or the cathode 212) of the cell 204. Although not shown in the illustrated embodiment, other foil extension regions may extend from each end of the first collector and the second current collector.

In one embodiment, current collector 206 collects electrons at the anode 208, and transfers the electrons through an anode tab (not shown), through elements of the testing unit 202, through a cathode tab (not shown), to the cathode 212, and to the current collector 214. In another embodiment, the current collectors can transfer electrons through the propulsion system 120 or other electrical systems of the vehicle 100.

The separator 210 can include a non-conductive, semi-permeable insulator, and electrolyte material or solution, which allows the passage of lithium ions, while blocking the passage of electrons. In one embodiment, solvent molecules in the electrolyte combine with lithium ions that pass through the separator 210, and form a solid electrolyte interface (SEI) at the anode 208. The SEI can prevent direct contact between the electrolyte and the electrons, thereby preventing the electrons from degrading the electrolyte.

In one embodiment, the mechanical excitation unit 216 is a vibrating motor physically connected to the cell 204. In the illustrated embodiment, the mechanical excitation unit 216 is disposed on the foil extension region 207 of the first current collector, however the mechanical excitation unit 216 can be disposed on or positioned at any external surface of the cell 204 that causes a movement or vibration of the current collector. For instance, the mechanical excitation unit 216 may be positioned at the anode tab, the cathode tab, or along a surface in contact with any combination of the first current collector, the foil extension region 207, the anode 208, the separator 210, the cathode 212, or the second current collector. The mechanical excitation unit 216 can also be disposed on, or positioned at, a foil consolidation unit (e.g., a terminal or consolidation weld) coupled to the foil extension region 207. For instance, the mechanical excitation unit 216 can be positioned at a consolidation weld connected to multiple foil extension regions of one end of the cell 204.

The electrical load 222 can represent the load of the vehicle 100 on the cell 204, such as the audio systems, display systems, navigation systems, temperature control systems, or other electrical systems of the vehicle 100.

The high-pass filter 218 can be used to filter a direct current (DC) component of an electrical signal while allowing any component of the electrical signal with a frequency higher than the cutoff frequency of the high-pass filter 218 to pass through. In one embodiment, the high-pass filter 218 includes a combination of inverters, capacitors, or resistors, that filter a DC component of an electrical signal generated by the current collector 206 during a mechanical excitation of the current collector 206.

The voltage measurement unit 220 may include a voltage sensor (e.g., a voltage sensor of the sensor system 108), a multimeter, a voltmeter, an oscilloscope, or the like. In one embodiment, the voltage measurement unit 220 is connected in series with the high-pass filter 218, and the combination of the voltage measurement unit 220 and high-pass filter 218 are connected in parallel with the cell 204 and the electrical load 222.

In the illustrated embodiment, the controller 140 is communicatively coupled to the voltage measurement unit 220, and the mechanical excitation unit 216. The controller 140 can be configured to control a vibration of the mechanical excitation unit 216, which can cause the first current collector to vibrate. Afterwards, the controller 140 can measure (via the voltage measurement unit 220) a voltage output of the cell 204, and determine damage (e.g., the presence of a tear or separation) of the first current collector foil. The controller 140 is described further in FIG. 3.

Although the illustrated embodiment shows a single cell of the testing unit 202, multiple cells can be connected to the cell 204 in parallel to form a cell group. Techniques disclosed herein can be applied to the cell group. Further, although some embodiments of the present disclosure discuss determining damage of the first current collector foils, techniques described herein can also be performed, in addition or in the alternative, on the second current collector to determine damage of the second current collector foil. Techniques for diagnosing the cell 204 are described further in FIG. 4 herein.

FIG. 3 illustrates a computing environment 300, according to an embodiment. In the illustrated embodiment, the computing environment 300 includes the controller 140, a network 330, and the testing unit 202.

In one embodiment, the controller 140 includes a processor 302 that obtains instructions and data via a bus 322 from a memory 304 or storage 308. Not all components of the controller 140 are shown. The controller 140 is generally under the control of an operating system (OS) suitable to perform or support the functions or processes disclosed herein. The processor 302 is a programmable logic device that performs instruction, logic, and mathematical processing, and may be representative of one or more CPUs. The processor may execute one or more algorithms, instruction sets, or applications in the memory 304 or storage 308 to perform the functions or processes described herein.

The memory 304 and storage 308 can be representative of hard-disk drives, solid state drives, flash memory devices, optical media, and the like. The storage 308 can also include structured storage (e.g., a database). In addition, the memory 304 and storage 308 may be considered to include memory physically located elsewhere. For example, the memory 304 and storage 308 may be physically located on another computer communicatively coupled to the controller 140 via the bus 322 or the network 330.

The controller 140 can be connected to other computers (e.g., controllers, distributed databases, servers, or webhosts) or testing unit 202 via a network interface 320 and the network 330. Examples of the network 330 include a controller area network (CAN), a transmission control protocol (TCP) bus, electrical busses, physical transmission cables, optical transmission fibers, wireless transmissions mediums, routers, firewalls, switches, gateway computers, edge servers, a local area network, a wide area network, a wireless network, or the like. The network interface 320 may be any type of network communications device allowing the controller 140 to communicate with computers and other components of the computing environment 300 via the network 330.

In the illustrated embodiment, the memory 304 includes a diagnostic module 306. In one embodiment, the diagnostic module 306 represents one or more algorithms, instruction sets, software applications, or other computer-readable program code that can be executed by the processor 302 to perform the functions, operations, or processes described herein.

In one embodiment, the diagnostic module 306 generates a signal that causes the mechanical excitation unit 216 to vibrate the cell 204, measures resultant voltages of the cell 204, and stores the voltages in the storage 308 as measurement data 310. The diagnostic module 306 can also determine resistances of the cell 204, and determine an amplitude of the voltages or resistances, which the diagnostic module 306 can use to determine damage present in the current collector foils of the cell 204. Afterwards, when damage is present in the current collector foils, the diagnostic module 306 can control the vehicle 100, generate a health report of the cell, or the like. Operation of the diagnostic module 306 is described further in FIG. 4 herein.

FIG. 4 illustrates a flowchart of a method 400 of diagnosing a cell, according to an embodiment. The method 400 begins at block 402.

At block 404, the diagnostic module 306 determines a current through a current collector of a battery cell. In one embodiment, the diagnostic module 306 performs the method 400 upon determining that a constant current is flowing through the cell 204. For instance, the method 400 may be performed while the cell 204 is discharging.

At block 406, the diagnostic module 306 generates a mechanical excitation to the current collector. In one embodiment, the diagnostic module 306 generates a signal that causes the mechanical excitation unit 216 to cause a vibration at the first current collector of the cell 204.

In one embodiment, when the first current collector includes a tear or a separation of the current collector foil, the vibration of the mechanical excitation unit 216 can cause a displacement of the current collector foil, which can cause the tear or separation to close or open. When the tear or separation is closed, current flow through elements of the testing unit 202 can increase. When the tear or the separation is open, current flow though elements of the testing unit 202 can decrease. Further, the vibrations may cause rapid opening and closing of the tear or the separation, which can cause transient voltage spikes that can be measured at the voltage measurement unit 220.

At block 408, the diagnostic module 306 determines an amplitude of a voltage across the battery cell based on the mechanical excitation. In one embodiment, the diagnostic module 306 determines an amplitude of the voltage spikes due to the rapid opening and closing of the tear or separation of the current collector foil.

In one embodiment, the high-pass filter 218 can filter the DC voltage generated by the cell 204, which allows the voltage measurement unit 220 to measure the changes in voltage (e.g., the voltage spikes) generated by the cell 204. In one embodiment, amplitude is determined within a frequency band with a lower cut off frequency greater or equal to 1 Hertz. Further, the testing unit 202 can include a band-pass filter with a center frequency matched to the frequency of a vibration of the mechanical excitation unit 216 to isolate electrical signals that reflect the frequencies of the vibration, and filter out high frequency and low frequency electrical noise. The diagnostic module 306 can also store timestamps corresponding to voltage measurements.

At block 410, the diagnostic module 306 determines a presence of a tear or a separation of a foil of the current collector based on the amplitude of the voltage across the battery cell. In one embodiment, the amplitude can be compared to a damage threshold that approaches 0 V (e.g., 10⁻¹⁵ V). Upon determining that the amplitude exceeds the threshold (i.e., upon determining that the cell 204 exhibits changes in voltage output due to the mechanical excitation), the diagnostic module 306 determines that the current collector foil includes a tear or separation.

In one embodiment, the method 400 is performed continuously. In this manner, the diagnostic module 306 can identify a timestamp corresponding to detection of the tear or the separation of the foil, thereby determining the time at which the tear or separation occurred.

In one embodiment, upon determining that there is a tear or a separation of a current collector foil of the cell 204, the diagnostic module 306 generates a health report of the cell 204. In another embodiment, the diagnostic module 306 generates a message to notify a user of the vehicle 100 that the cell includes a tear or a separation of a current collector foil. In yet another embodiment, the diagnostic module 306 controls an operation (e.g., slowing or stopping the vehicle) of the vehicle 100 to prevent use of the cell 204 that includes the damaged current collector foil. The method 400 ends at block 412.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A method of diagnosing a battery cell of a vehicle, comprising:
determining that a current is flowing through a current collector of the battery cell;
generating a mechanical excitation to the current collector;
determining an amplitude of a voltage across the battery cell based on the mechanical excitation; and
determining a presence of a tear or a separation of a foil of the current collector based on the amplitude of the voltage across the battery cell.

2. The method of claim 1, further comprising:
determining a time at which the tear or the separation of the foil of the current collector occurred.

3. The method of claim 1, wherein the mechanical excitation is generated via a mechanical excitation unit disposed on or positioned at an external surface of the battery cell or a foil consolidation unit coupled to the battery cell.

4. The method of claim 3, wherein the external surface includes one of: an anode tab of the battery cell; a cathode tab of the battery cell; or a surface in contact with a combination of an anode of the battery cell, a current collector at the anode, a foil extension region of the current collector at the anode, a cathode of the battery cell, a current collector at the cathode, a foil extension region of the current collector at the cathode, or a separator of the battery cell.

5. The method of claim 1, wherein the mechanical excitation causes a displacement of the foil of the current collector, and wherein the displacement of the foil causes the tear or the separation to close and to open.

6. The method of claim 1, wherein the voltage across the battery cell is passed through a high-pass filter or a band-pass filter before being measured by a voltage measurement unit.

7. The method of claim 5, wherein the amplitude is determined within a frequency band with a lower cut off greater or equal to 1 Hertz.

8. A system for diagnosing a battery cell of a vehicle, comprising:
a processor; and
memory or storage comprising an algorithm or computer instructions, which when executed by the processor, performs an operation comprising:
determining that a current is flowing through a current collector of the battery cell;
generating a mechanical excitation to the current collector;
determining an amplitude of a voltage across the battery cell based on the mechanical excitation; and
determining a presence of a tear or a separation of a foil of the current collector based on the amplitude of the voltage across the battery cell.

9. The system of claim 8, the operation further comprising:
determining a time at which the tear or the separation of the foil of the current collector occurred.

10. The system of claim 8, wherein the mechanical excitation is generated via a mechanical excitation unit disposed on or positioned at an external surface of the battery cell or a foil consolidation unit coupled to the battery cell.

11. The system of claim 10, wherein the external surface includes one of: an anode tab of the battery cell; a cathode tab of the battery cell; or a surface in contact with a combination of an anode of the battery cell, a current collector at the anode, a foil extension region of the current collector at the anode, a cathode of the battery cell, a current collector at the cathode, a foil extension region of the current collector at the cathode, or a separator of the battery cell.

12. The system of claim 8, wherein the mechanical excitation causes a displacement of the foil of the current collector, and wherein the displacement of the foil causes the tear or the separation to close and to open.

13. The system of claim 12, wherein the amplitude is determined within a frequency band with a lower cut off greater or equal to 1 Hertz.

14. The system of claim 8, wherein the voltage across the battery cell is passed through a high-pass filter or a band-pass filter before being measured by a voltage measurement unit.

15. A computer-readable storage medium having a computer-readable program code embodied therewith, the computer-readable program code executable by one or more computer processors to perform an operation for diagnosing a battery cell of a vehicle, the operation comprising:
determining that a current is flowing through a current collector of the battery cell;
generating a mechanical excitation to the current collector;
determining an amplitude of a voltage across the battery cell based on the mechanical excitation; and
determining a presence of a tear or a separation of a foil of the current collector based on the amplitude of the voltage across the battery cell.

16. The computer-readable storage medium of claim 15, the operation further comprising:
determining a time at which the tear or the separation of the foil of the current collector occurred.

17. The computer-readable storage medium of claim 15, wherein the mechanical excitation is generated via a mechanical excitation unit disposed on or positioned at an external surface of the battery cell or a foil consolidation unit coupled to the battery cell, and wherein the external surface includes one of: an anode tab of the battery cell; a cathode tab of the battery cell; or a surface in contact with a combination of an anode of the battery cell, a current collector at the anode, a foil extension region of the current collector at the anode, a cathode of the battery cell, a current collector at the cathode, a foil extension region of the current collector at the cathode, or a separator of the battery cell.

18. The computer-readable storage medium of claim 15, wherein the mechanical excitation causes a displacement of the foil of the current collector, and wherein the displacement of the foil causes the tear or the separation to close and to open.

19. The computer-readable storage medium of claim 18, wherein the amplitude is determined within a frequency band with a lower cut-off greater or equal to 1 Hertz.

20. The computer-readable storage medium of claim 15, wherein the voltage across the battery cell is passed through a high-pass filter or a band-pass filter before being measured by a voltage measurement unit.
